(19) United States
(12) Patent Application Publication
(10) Pub. No.: US 2006/0035470 A1
(43) Pub. Date: Feb. 16, 2006

(54) Method for manufaturing semiconductor device and substrate processing system

(75) Inventors: Sadayoshi Horii, Tokyo (JP); Hironobu Miya, Tokyo (JP)

Correspondence Address: OLIFF & BERRIDGE, PLC, P.O. BOX 19928, ALEXANDRIA, VA, 22320, US

(73) Assignee: Hitachi Kokusai Electronic, Inc., Nakano-ku, Tokyo (JP)

(21) Appl. No.: 10/529,466

(22) PCT Filed: Oct. 24, 2003
(86) PCT No.: PCT/JP03/13606

§ 371 Date: Mar. 29, 2005

(30) Foreign Application Priority Data
Oct. 30, 2002 (JP) 2002-316154

(51) Int. Cl. H01L 21/469; C23C 16/00

(52) U.S. Cl. 438/758; 118/715; 438/778; 438/761

(57) ABSTRACT

To improve throughput of a substrate processing without wastefully using a source as a reactant by repeating supply steps of a plurality of reactants for a plurality of times. A substrate processing apparatus includes a source gas obtained by vaporizing a liquid source as a reactant, and functions to process a substrate by repeating the supply of the source gas into a processing chamber 1, and the supply of the reactant different from the source gas into the processing chamber 1, which is executed subsequently, for a plurality of times. A flow rate of the liquid source is controlled by an injection drive control mechanism 6. The injection drive control mechanism 6 is designed to fix the flow rate per one injecting operation of the liquid source directly flowing into a vaporization section in a vaporizer 3, and intermittently inject the liquid source to a vaporization section 31.

### TECHNICAL FIELD

The present invention relates to a manufacturing method of a semiconductor device and a substrate processing apparatus, particularly to the substrate processing apparatus for processing the substrate by using a reaction product containing a source gas obtained by vaporizing a liquid source.

### BACKGROUND ART

Generally, a substrate processing apparatus for manufacturing a semiconductor device which processes the substrate by using a liquid source requires a liquid source vaporizing system for vaporizing the liquid source. The gas (referred to as vaporized gas hereafter) vaporized by increasing the temperature of the liquid source in the liquid source vaporizing system must be prevented from being liquefied at a high temperature. Therefore, piping has to be heated if needed. Particularly, a source in a gas state of vaporized metal has a low vapor pressure and is liquefied by being cooled by piping. Therefore, the piping needs to be heated. In order to process a substrate by use of such a vaporized gas, a flow of the vaporized gas has to be properly controlled. A method of using a valve is given as the easiest method of controlling the flow of the vaporized gas.

However, when the flow of the vaporized gas is controlled by simply using the valve, the valve is also required to be heated. However, generally, a heating type valve has a shorter service life. Repeated opening and closing of the valve poses a fear that the service life of the valve comes to an end by 100-day use, according to our estimates. Furthermore, even when the vaporized gas is controlled with a valve, a problem is that the vaporized gas source is adsorbed on the interior of the valve, particularly on a driving part, and by reaction that occurs there, a film is peeled off to generate particles. The adsorption of the particles on a wafer surface becomes a cause of a failure of a chip as a minimum processing dimension of the semiconductor device becomes smaller, and therefore has to be prevented as much as possible. Furthermore, while a valve is closed, there is a possibility that the pressure of the pipe to transfer the vaporized gas rises, and the gas is thereby liquefied. By the liquid generated here, a film is formed on the interior of the pipe by a self-decomposing reaction, and the piping diameter is thereby gradually made to be smaller, thus posing the problem of clogging the pipe.

Therefore, when a flow of a source is controlled by use of a valve, it is probable that the flow of the source is controlled in a liquid state before vaporization. This is because in a liquid state, molecules that constitute the source is not activated, and therefore the film is hard to be formed compared with a case of a gas state. Generally, in order to control a flow rate of the liquid source, a feedback control system is executed according to flow rate information. However, a problem involved in the feedback control of the liquid source is that controllability is extremely inferior compared with a case in which a flow rate control object is a vaporized gas. Therefore, various methods have been proposed to overcome the problems.

For instance, a liquid metal vaporization section for CVD system has a liquid-mass flow controller and a vaporizer. In the flow rate controller, a valve for opening and closing its flow passage can be controlled by both pulse width and frequency, and the liquid metal controlled by the flow rate controller is intermittently introduced in the form of fine particles into the vaporizer. (patent document 1).

Furthermore, a feeding apparatus for liquid source using a MOCVD method has a pressure chamber with its volume changed by drive of a piezoelectric element, an introducing section for introducing the liquid source to the pressure chamber, a spouting nozzle for spouting and vaporizing the liquid source compressed in the pressure chamber, and a control section for controlling an spouting amount of the liquid source. Note that the vaporizer is not included. A drive voltage pulse generated in a power supply circuit of the controller is applied to the piezoelectric element to control the spouting amount of the liquid source (patent document 2).

Still furthermore, a mass-flow controller of a CVD device has a control device for supplying a control signal used to make a liquid-phase material flow out at a prescribed flow rate to a flow rate control valve, and a flow rate control valve provided with a liquid drop output structure for outputting the flowing-in liquid-phase material as a liquid drop. In addition, the liquid drop output structure has the pressure chamber for storing the liquid-phase material and a diaphragm capable of changing the volume of the pressure chamber, and the piezoelectric element for deforming the diaphragm by changing the volume of the pressure chamber corresponding to the control signal. (patent document 3).

Furthermore, in a thin film growing method using an ALD (Atomic Layer Deposition) method, a vaporized reactant is introduced from the reactant source via a first conduit into the reaction chamber. The above reactant is supplied repeatedly in the form of a vapor-phase pulse alternately with a vapor-phase pulse of at least one other reactant into the above reaction chamber and allowed to react with the surface of the substrate, by which a thin film compound is deposited on the substrate. By supplying, between the respective vapor-phase pulses of the different reactants, inert gas into the first conduit via a second conduit connected to the above first conduit a vapor-phase barrier is formed against the flow of the vapor-phase reactant flowing from the reactant source-via the first conduit into the reaction chamber. Then, by using the vapor-phase barrier, high speed switching of the source is performed in a valveless shape. (patent document 4).

Patent document 1: Japanese Patent Laid Open No. 2002-173777

Patent document 2: Japanese Patent Laid Open No. 2002-175987

Patent document 3: Japanese Patent Laid Open No. 2000-121400

Patent document 4: Japanese Patent Laid Open No. 2002-4054

### DISCLOSURE OF INVENTION

The following problems are involved in the above-described conventional technique. A method of manufacturing a semiconductor device according to the patent documents 1 to 3 is provided with a mechanism to control and drive the injection of the liquid source so as to be intermittently injected, with the flow rate per one injecting operation of the liquid fixed, and a method of controlling the flow rate is designed to control the flow rate by the number of injection. However, it is assumed that the aforementioned methods are all applied to the CVD method and the MOCVD method using a process of supplying plural reactants to the substrate by mixing together. Accordingly, switching of the plural reactants is not assumed, and therefore when applied to a device manufacturing method such as the ALD method using the process of supplying the plural reactants by switching, the plural reactants can not be switched at a high speed. Therefore, the number of injection is increased compared with the CVD method and the MOCVD method, thus posing a problem that a throughput can not be improved.

In this point, according to the patent document 4, the reactant can be switched at a high speed by using the vapor-phase barrier. Therefore, in the thin film growing method using the ALD method, the throughput can be improved. However, when performing a high speed switching of the source, which is a reactant, by using the vapor-phase barrier, the source is continuously supplied. Therefore, a disadvantage involved therein is that the source is wastefully used other than introducing into the reaction chamber, thus increasing the cost accordingly.

An object of the present invention is to provide a method of manufacturing a semiconductor device and a substrate processing apparatus capable of improving a throughput of substrate processing, without wastefully using a source, which is a reactant, in processing the substrate by repeating the supply step of plural reactants for a plurality of times.

Then, the present invention takes several aspects as follows.

In a first aspect, a method of manufacturing a semiconductor device is provided, comprising:
supplying one reactant to a substrate;
supplying the other reactant to the substrate; and
processing the substrate by repeating the above steps for a plurality of times,
wherein both or either of the reactants contains a source gas obtained by vaporizing a liquid source in a vaporization section, a flow rate of the liquid source to the vaporization section per one injecting operation is fixed, and the liquid source is controlled to be intermittently injected to the vaporization section.

Since an amount of injection of the liquid source that flows in the vaporization section that vaporizes the liquid source is directly controlled, a certain amount of the liquid source can be vaporized in a shorter period of time and a certain amount of the source gas can be supplied from the vaporization section to the substrate in a shorter period of time. Accordingly, when the substrate is processed by repeating the supply of the plural reactants containing the gas obtained by vaporizing the liquid source in the vaporization section for a plurality of times, the supply of the reactants can be repeated at a high speed, and the throughput of the substrate processing can be thereby improved.

In a second aspect, the method of manufacturing the semiconductor device according to the first aspect is provided, wherein the flow rate of the liquid source to the vaporization section per one injecting operation is made equal to the flow rate corresponding to one supplying operation of the source gas obtained by vaporizing in the vaporization section to the substrate. When the flow rate per one injecting operation of the liquid source to the vaporization section is made equal to the flow rate corresponding to one supplying operation of the reactant to the substrate, the control becomes easy.

In a third aspect, the method of manufacturing the semiconductor device according to the first aspect is provided, wherein the flow rate of the liquid source to the vaporization section per one injecting operation is made smaller than the flow rate corresponding to one supplying operation of the source gas obtained by vaporizing in the vaporization section to the substrate, and the flow rate is controlled by the number of injection. When the flow rate in one injecting operation of the liquid source to the vaporization section is made smaller than the flow rate corresponding to one supplying operation of the reactant to the substrate and the flow rate is controlled by the number of injection, during one supplying operation, a non-injection period during which the liquid source is not injected to the vaporization section is generated, and in this period, a temperature of the vaporization section can be recovered. Accordingly, the vaporization efficiency can be inhibited from deteriorating due to a temperature drop at the vaporization section.

In a fourth aspect, the method of manufacturing the semiconductor device according to the first aspect is provided, wherein the process is an ALD processing to form a film with a desired thickness by repeating for a plurality of times of the control of:
supplying the one reactant to the substrate so as to be adsorbed thereon; and
supplying the other reactant to the reactant thus adsorbed on the substrate to cause reaction, thereby forming a film.

By repeating the deposition step and the reformation step for a plurality of times, the ALD processing is also effective for the processing (referred to as an MRCVD processing or an MRCVD method hereafter) to form the desired film. However, in the ALD processing to form the film of the desired thickness by repeating an adsorption step and the deposition step for a plurality of times, the film thickness formed by one cycle is determined, and therefore the number of injection is increased compared with the MOCVD processing. However, the speed can be repeatedly increased, and this significantly contributes to improving the throughput.

In a fifth aspect, a substrate processing apparatus is provided, comprising:
a processing chamber for processing a substrate;
a container for containing a liquid source;
a vaporizer having a vaporization section for vaporizing the liquid source;
a liquid source supply pipe for supplying the liquid source contained in the container to the vaporizer;
a source gas supply pipe for supplying the source gas obtained by vaporizing in the vaporizer into the processing chamber;
an injection drive control mechanism for controlling so as to fix a flow rate per one injecting operation to the vaporization section, and intermittently inject the liquid source to the vaporization section;
a supply pipe for supplying a reactant different from the source gas into the processing chamber; and
a controller for controlling so as to repeat the supply of the source gas to the processing chamber and the supply of the reactant gas different from the source gas, for a plurality of times.

When a substrate processing apparatus is provided with an injection drive control mechanism for controlling the injection of the liquid source to be intermittently injected to the vaporizer by fixing the flow rate of the liquid source per one injecting operation to the vaporize and a controller for controlling the supply of the reactant different from the source gas into the processing chamber so as to be repeated for a plurality of times, the method of manufacturing the semiconductor device of the first aspect can be easily executed.

In a sixth aspect, the substrate processing apparatus according to the fifth aspect is provided, wherein the controller has a function to control the flow rate of the liquid source per one injecting operation to the vaporizer so as to be made equal to an amount corresponding to one supplying operation of the source gas obtained by vaporizing in the vaporization section to the substrate. When the controller has such a function, the method of manufacturing the semiconductor device of the second aspect can be easily executed.

In a seventh aspect, the substrate processing apparatus according to the fifth aspect is provided, wherein the controller further has a function to make the flow rate of the liquid source to the vaporization section per one injecting operation smaller than the flow rate corresponding to one supplying operation of the source gas obtained by vaporizing in the vaporization section to the substrate, and control the flow rate by the number of injection. When the controller has such a function, the method of manufacturing the semiconductor device of the third aspect can be easily executed.

In an eighth aspect, the substrate processing apparatus according to the fifth aspect is provided, wherein the controller further has a function to control so as to deposit on the substrate by using an ALD, by repeating for a plurality of times a step of supplying one reactant to the substrate to be adsorbed thereon, and a step of forming a film by supplying other reactant to the reactant already adsorbed on the substrate so as to be reacted thereon. When the controller has such a function, the method of manufacturing the semiconductor device of the fourth aspect can be easily executed.

In a ninth aspect, the substrate processing apparatus according to the fifth aspect is provided, wherein the controller further has a function to previously measure the correlation between a pressure for feeding the liquid source to the vaporization section and the flow rate per one injecting operation, and correct the flow rate per one injecting operation based on the correlation thus obtained. When the controller has a function to correct the flow rate based on the correlation between the pressure and the flow rate, the flow rate per one injecting operation to the vaporization section can be fixed without being affected by the change of pressure.

In a tenth aspect, the substrate processing apparatus according to the fifth aspect is provided, wherein a liquid flow meter is provided between the vaporization section and the container, and an injection drive control mechanism having a flow rate adjusting mechanism electrically connected to the liquid flow meter is installed, and the flow rate adjusting mechanism has a controller that calculates an integrated flow rate of a certain time period or a certain constant number of injection based on an electrical signal from the liquid flow meter, monitors the integrated flow rate thus obtained with passage of time, and adjusts a change in the flow rate to the vaporization section per one injecting operation with passage of time. When the controller has a function to adjust the change of the flow rate with passage of time per one injecting operation to the vaporization section, the flow rate per one injecting operation to the vaporization section can be fixed, without being influenced by the change of the injection drive control mechanism and the vaporization section with passage of time.

In an eleventh aspect, the substrate processing apparatus according to the fifth aspect is provided, wherein the vaporizer is constituted as an injection type vaporizer integrally comprising the vaporization section for vaporizing the liquid source, a flow passage for feeding the liquid source to the vaporization section, and a valve element for controlling the injection/non-injection of the liquid source to the vaporization section by opening/closing the valve, and controlling the flow rate of the liquid source fed to the flow passage in controlling the opening by adjusting an opening degree of the valve, wherein the adjustment of the opening degree and opening/closing of the valve element is performed by the injection drive control mechanism. When the valve element is designed to control the liquid source so as to be supplied to the vaporization section by using the vaporizer integrally having the valve element, controllability is improved compared with the vaporizer having the valve element separately, and an excellent volatilization characteristics can thereby be obtained. In addition, since the valve element is constituted so that the degree of opening can be adjusted as well as adjusting opening/closing, the flow rate of the liquid source already fixed by one injecting operation to the vaporization section can also be corrected.

In a twelfth aspect, the method of manufacturing the semiconductor device according to the first aspect is provided, wherein when any one of the reactants is a gas obtained by vaporizing the liquid source at the vaporization section, and any one of other reactants is a reactive gas different from the vaporized gas, the supply of the reactive gas to the substrate is controlled by opening/closing the valve, and the flow rate of the reactive gas is controlled by a restrictor provided on the flow passage. When the reactive gas is controlled by opening/closing and restrictor of the valve, the reactive gas can be controlled at higher speeds than a mass flow controller. Accordingly, when the substrate is processed by repeating the supply of the vaporized gas and the reactive gas for a plurality of times, the supply of not only the vaporized gas but also the reactive gas can be repeated at a high speed. Therefore, the throughput of the substrate processing can be further improved. In this case, when the reactive gas is activated with plasma and supplied to the substrate, a preliminary plasma may be generated prior to the generation of the aforementioned plasma. When the reactive gas is activated by generating the preliminary plasma, the reactive gas can be activated instantly by the actual plasma. Accordingly, even when the reactive gas is activated by the plasma and supplied to the substrate, the throughput of the substrate processing can be more improved.

### BRIEF DESCRIPTION OF THE DRAWINGS

FIG. 1 is a block diagram showing a substrate processing apparatus for performing a method of manufacturing a semiconductor device according to the present invention.

FIG. 2 is a vertical sectional view of a vaporizer according to an embodiment.

FIG. 3 is a comparative explanatory view between a conventional example and an embodiment showing the vaporization characteristics responding to controller (control device) instructions, FIG. 3(A) shows a conventional example, and FIG. 3(B) shows an embodiment.

FIG. 4 is an overall block diagram of an ALD device that is used in a cluster type semiconductor manufacturing device according to the embodiment.

FIG. 5 is a block diagram of an essential portion of the ALD device according to the embodiment.

FIG. 6 is a view of a reactant supply sequence of an ALD method according to the embodiment.

FIG. 7 is a view of a reactant supply sequence of the ALD method according to the embodiment.

FIG. 8 is a timing chart comparing an injection method between the embodiment and the conventional example.

FIG. 9 is a characteristic diagram according to the embodiment measuring the relation between the injection flow rate and a N₂ feeding pressure with an opening of a valve element as a parameter.

FIG. 10 is a block diagram of the substrate processing apparatus for performing a method of manufacturing the semiconductor device according to the embodiment.

FIG. 11 is a block diagram of a reactive gas supply system according to the embodiment.

FIG. 12 is a diagram of the reactant supply sequence of the ALD method in consideration of the reactive gas supply system according to the embodiment.

FIG. 13 is an explanatory view of a remote plasma unit capable of generating preliminary plasma according to the embodiment.

FIG. 14 is a schematic block diagram of a small plasma generator that can generate preliminary plasma according to the embodiment.

FIG. 15 is a schematic block diagram of the reactive gas supply system according to the embodiment.

FIG. 16 is a diagram of an essential portion of the reactive gas supply system according to the embodiment.

### REFERENCE NUMERALS

| | |
|---|---|
| 1 | processing chamber |
| 2 | container |
| 3 | vaporizer |
| 4 | liquid source supply pipe |
| 5 | source gas supply pipe |
| 6 | injection drive control mechanism |
| 7 | supply pipe |
| 8 | controller |
| 31 | vaporization section |

### BEST MODE FOR CARRYING OUT THE INVENTION

Embodiments of the present invention will be explained hereafter.

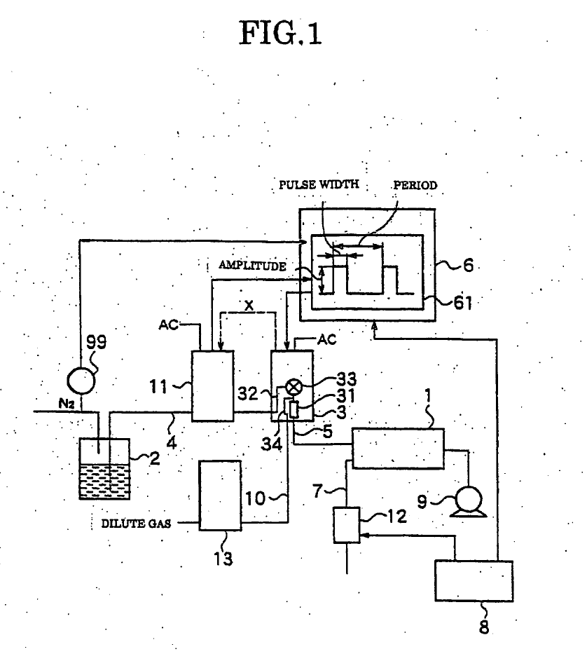

FIG. 1 is a block diagram of a device for performing a method of manufacturing a semiconductor device, which is an example of a substrate processing apparatus, wherein a liquid law material vaporizing system is adopted. The method of manufacturing the semiconductor device adopted by this substrate processing apparatus comprises:
supplying one reactant on a substrate;
supplying other reactant to the substrate; and
processing the substrate by repeating the above steps for a plurality of times.

The substrate processing apparatus comprises a processing chamber 1, a source container 2, a vaporizer 3, a liquid source supply pipe 4, a source gas supply pipe 5, an injection drive control mechanism 6, a reactive gas supply pipe 7, and a controller 8.

The processing chamber 1 is constituted so that a substrate may be processed internally, and connected to a pump 9 so as to be exhausted therefrom.

The source container 2 is constituted so that the liquid source is contained therein and the liquid source thus contained is forcibly fed under pressure of an inert gas such as He, Ar and N₂ to the vaporizer 3 through the liquid source supply pipe 4.

By the vaporizer 3, the liquid source, whose temperature is increased, is vaporized, and the source gas is generated as a reactant. The vaporizer 3 integrally comprises a vaporization section 31 for vaporizing the liquid source, a liquid source flow path 32 for feeding the liquid source to the vaporization section 31, a liquid flow controlling valve element 33 that controls injection/non-injection of the liquid source to the vaporization section 31 by opening and closing a valve, and controls the flow rate of the liquid source sent to the liquid source flow path 32, in controlling the opening of the valve by adjusting the opening degree of the valve, and a dilute gas flow path 34 connected to the liquid source flow path 32 located downstream from the valve element 33, for feeding a dilute gas for diluting the liquid source which is sent to the vaporization section 31.

By the dilute gas supply pipe 10, a dilute gas supply source not shown and the dilute gas flow path 34 of the vaporizer 3 are connected, and the dilute gas is supplied to the vaporizer 3 from the dilute gas supply source through a mass flow controller 13.

By the liquid source supply pipe 4, the source container 2 and the liquid source flow path 32 of the vaporizer 3 are connected, and the liquid source contained in the source container 2 is supplied to the vaporizer 3 through a liquid flow meter 11.

By the source gas supply pipe 5, the vaporization section 31 of the vaporizer 3 and the processing chamber 1 are connected, and the source gas obtained by vaporizing in the vaporizer 3 as a reactant is supplied to the substrate in the processing chamber 1.

By the reactive gas supply pipe 7, a reactive gas supply source not shown for supplying the reactive gas as other reactant and the processing chamber 1 are connected, and the reactive gas is supplied to the substrate in the processing chamber 1. The reactive gas is controlled in flow rate by a controller mechanism 12 provided in the reactive gas supply pipe 7. The mass flow controller may be used in the controller mechanism 12. However, preferably the controller mechanism with high operating speed is used in accordance with an injection drive control mechanism 6 for controlling the flow rate of the liquid source at a high speed and the vaporizer 3.

The injection drive control mechanism 6 functions to intermittently inject the liquid source to the vaporization section 31 by fixing the flow rate of the liquid source per one injecting operation to the vaporization section 31 of the vaporizer 3. Accordingly, the injection drive mechanism 6 has a flow rate adjusting mechanism 61 operable under a program, and the flow rate adjusting mechanism 61 is electrically connected to the vaporizer 3, so that the vaporizer 3 is operated according to an instruction from the injection drive control mechanism 6. Specifically, a pulse-like electrical signal constituted of amplitude, pulse width, and period is applied to the valve element 33 of the vaporizer 3, and the valve element 33 is subjected to open-loop control.

In accordance with the amplitude, the opening degree of the valve element 33 is determined, and the liquid source is injected by opening the valve for a period corresponding to the pulse width. Also, the number of injection is determined in accordance with the period. The flow rate per one injecting operation of the liquid source to the vaporizer section 31 is fixed by the amplitude and the pulse width. Moreover, the number of injection per one supplying operation (1 step) for supplying the vaporized gas to the substrate in accordance with the period is determined, and in accordance with the number of the injection and the aforementioned amplitude and pulse width, a total amount of the injection flow rate per one step is determined. These values can be set beforehand in the flow rate adjusting mechanism 61 by a user, or can be automatically changed based on a program.

As described above, the flow rate per one injecting operation of the liquid source to the vaporization section 31 is fixed, and such flow rate is usually determined to be fixed under a predetermined injecting pressure. However, according to a fluctuation in the injecting pressure, in some cases, the fixed flow rate needs to be corrected. Depending on a use mode that necessitates such collection of the flow rate, the flow rate is corrected by adjusting the opening degree of the valve element 33, that is, the amplitude integrally provided in the vaporizer 3. Note that the flow rate may be corrected not only by the amplitude, but also by the pulse width, or the amplitude and the pulse width.

Furthermore, when the injection drive control mechanism 6 and the vaporizer 3 are used for a long time, an aging effect occurs to an injecting amount, and therefore the fixed flow rate needs to be adjusted in some cases. Depending on a use mode such as adjusting the aging effect of the injecting amount, the injection drive control mechanism 6 is electrically connected not only with the vaporizer 3 but also with the liquid flow meter 11, and the valve is adjusted according to a command from the injection drive control mechanism 6. That is, the flow rate detected by the liquid flow meter 11 is notified to the injection drive control mechanism 6, and based on the flow rate thus notified, an integrated flow rate of the number of injection is determined, and such an integrated flow rate is monitored by the flow rate adjusting mechanism 61. Then, in accordance with the monitor result, the valve element 33 of the vaporizer 3 is controlled so as to adjust the injecting amount by the command from the injection drive control mechanism 6.

Note that in the injection drive control mechanism 6, a signal from a pressure gauge 66 is input, for measuring pressure in the piping that supplies the inert gas such as N₂ to the source container 2, and the pressure in the pipe can be monitored by the flow rate adjusting mechanism 61.

The controller 8 controls the controller mechanism 12 and the injection drive control mechanism 6 so as to repeat supplying the source gas obtained by vaporizing in the vaporizer 3 to the processing chamber 1 and subsequently supplying the reactive gas different from the source gas to the processing chamber 1 for a plurality of times.

Note that the designation mark AC shown in the liquid flow meter 11 and the vaporizer 3 in FIG. 1 means an AC power source.

Action of the aforementioned substrate processing apparatus will be explained hereunder.

A method of forming a film by repeating the aforementioned supplying steps of a reactant for a plurality of times includes a MRCVD method and an ALD method, for example. In the ALD method, with low processing temperature and low pressure, the film with a desired thickness is formed by forming the film in each atomic layer. Meanwhile, in the MRCVD method with higher processing temperature and pressure than the ALD method, the film with a desired thickness is formed by forming a thin film (several to several tens atomic layers) for a plurality of times. When the temperature is high, the MRCVD method is adopted, and when the temperature is low, the ALD method is adopted. The method of manufacturing the semiconductor device is applicable to either case of such methods.

The semiconductor device is manufactured by performing the method mainly including the following three steps by using the aforementioned substrate processing apparatus.

(1) A step of supplying the source gas as one reactant made by the vaporized liquid source to the substrate.

(2) A step of supplying the reactive gas that is other reactant to the substrate.

(3) A step of repeating the source gas supplying step and the reactive gas supply step for a plurality of times.

The above steps will be individually explained hereunder.

(1) A Step of Supplying the Vaporized Gas as a Reactant Obtained by Vaporizing the Liquid Source to the Substrate

The value of the flow rate to be injected to the vaporization section 31 is previously set in the injection drive control mechanism 6. In this condition, the processing chamber 1 is evacuated by a pump 9 to set to be a predetermined pressure, and the substrate in the processing chamber 1 is heated to a predetermined temperature. The liquid source is sent under pressure by a N₂ gas from the source container 2 to the liquid source supply pipe 4, and the liquid source thus sent is supplied to the vaporizer 3 through the liquid flow meter 11. In the vaporizer 3, the pulse amplitude, the pulse width, the pulse-like control electrical signal are applied to the valve element 33 from the injection drive control mechanism 6, and the liquid source is injected to the vaporization section 31 for a time corresponding to the pulse width.

Here, the flow rate per one injecting operation of the liquid source is fixed, thereby having a high response to the injecting operation, compared with a case of changing the flow rate by a feedback control. In addition, the pulse-like injection of the liquid source fixed in flow rate per one injecting operation is performed, a supply amount of the liquid source can be adjusted according to the number of injection, even if the flow rate per one injecting operation is fixed. Further, neither an external piping communicating with the vaporizer 3 nor a flow path communicating with the vaporization section 31 in the vaporizer 3, but the flow rate of the liquid source that is injected to the vaporization section 31 for vaporizing the liquid source is directly controlled. Accordingly, compared with the case where a injecting amount of the liquid source that flows in the external piping communicating to the vaporizer 3 or a flow path communicating to the vaporization section 31 in the vaporizer 3 is controlled, a fixed amount of liquid source can be vaporized in a shorter period of time and from the vaporization section 31, a fixed amount of source gas can be supplied on a substrate in a shorter period of time.

(2) A Step of Supplying the Gas Which is Other Reactant to the Substrate

After the vaporized gas is supplied into the processing chamber, the reactive gas as other reactant is sent to a reactive gas supply pipe 7 from the reactive gas supply source not shown, and is supplied to the substrate in the processing chamber 1 through the controller mechanism 12. Other reactant whose flow rate is controlled by the controller mechanism 12 is in a gas state but not liquid at normal temperature. Accordingly, even when the mass flow controller serving as the feedback control is used in the controller mechanism 12, good controllability can be obtained. As a result, quick operation can be guaranteed, such as supplying a fixed flow amount of source gas to the substrate in a short period of time. Particularly, when the controller mechanism 12 having quick operation speed is used in accordance with the injection drive control mechanism 6 for controlling the flow rate of the liquid source at a high speed, further quick operation can be guaranteed.

(3) A Step of Repeating the Vaporized Gas Supply Step and the Reactive Gas Supply Step for a Plurality of Times

By controlling the controller mechanism 12 and the flow rate adjusting mechanism 61 by the controller 8, the supply of the vaporized gas and the supply of the reactive gas to the substrate are repeated for a plurality of times, and the film with a desired thickness is thereby formed on the substrate.

According to the abovementioned method of manufacturing the semiconductor device, not only the fixed amount of vaporized gas but also the fixed amount of the reactive gas can be supplied to the substrate in a short period time, and therefore a plurality of gases can be switched at a high speed. Accordingly, in a process in which the plurality of gases are supplied by switching as shown in the embodiment, the throughput of the film deposition treatment can be improved.

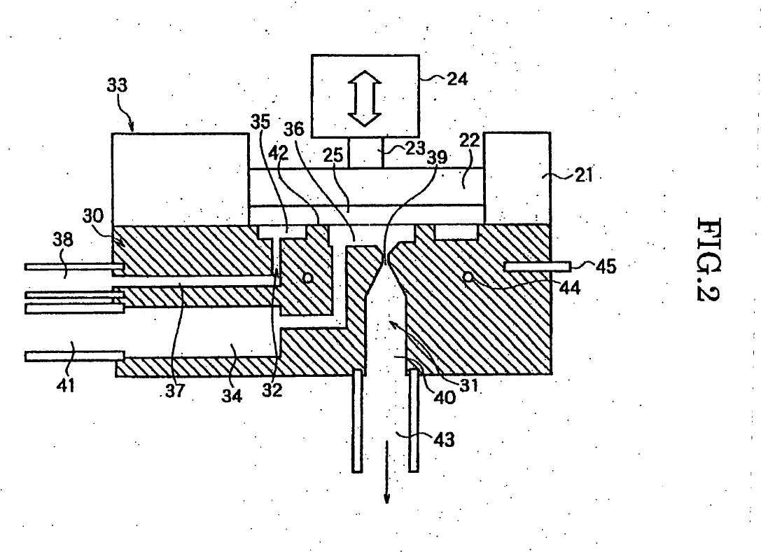

FIG. 2 shows an example of a structure of a vaporizer suitable for being used in the abovementioned substrate processing apparatus. In the vaporizer, a liquid flow rate control valve element is provided integrally with a main body and in general this is called an injection type vaporizer. The vaporizer 3 mainly has a vaporizer main body 30, a liquid flow rate control valve element 33 for controlling the supply of the liquid source and a vaporization section disposed immediately under the valve element 33.

In the vaporizer body 30, the liquid source and the dilute gas are mixed and sprayed, and then heated to be vaporized. The vaporizer main body 30 is made of a metal cylindrical block. As a material thereof, for instance, stainless steel, stainless steel coated with Teflon (registered trade mark) and so on can be used. On a top surface of the vaporizer body 30, a liquid filling container 35 and a mixing container 36 are provided.

The liquid filling container 35 is provided, so that the liquid source is stored when closing the valve element 33, and the liquid source thus stored is uniformly sent in the mixing container 36 from an outer periphery of the mixing container 36 when opening the valve element 33. For that purpose, the liquid filling container 35 is formed, with an upper surface of the vaporizer main body 30 recessed in the form of a ring. A bottom portion of the liquid filling container 35 is communicated to a liquid lead-in port 38 provided on the side face of the vaporizer main body 30 through a liquid source lead-in path 37 provided in the vaporizer body 30. When the valve element 33 is closed, the liquid source is stored in the liquid filling container 35, and when the valve element 33 is opened the liquid filling container 35 and the mixing container 36 are communicated to each other, and the liquid source stored in the liquid filling container 35 is sent into the mixing container 36. According to vertical position of the valve element 33, the flow rate of the liquid source fed into the mixing container 36 is changed. The liquid source flow path 32 of the present invention is constituted of the liquid filling container 35, the mixing container 36, the liquid source lead-in path 37, and the liquid lead-in port 38.

The mixing container 36 is provided so that the liquid source sent thereinto from the liquid filling container 35 is diluted by mixing with the dilute gas, and the liquid source is easily vaporized by adjusting a push-out quantity thereof from an orifice 39 provided on the bottom of the mixing container 36. In addition, by providing the mixing container 36, the dilute gas always flows into the vaporizer main body 30, by relaying the mixing container 36 even if the valve element 33 is in a closing state. Here, the reason for flowing the dilute gas in the vaporizer main body 30 even when the valve element 33 is closed is that when the valve element 33 is closed, a residual liquid source is removed from the mixing container 36 and a vaporization container 40 and the dilute gas is always kept flowing thereinto, thereby increasing the switching speed from supply to stop of the vaporized gas, and from stop to supply of the vaporized gas. Note that the vaporization section 31 is constituted of the aforementioned orifice 39 and the vaporization container 40.

The mixing container 36 is formed in the inside of the ring-shaped liquid filling container 35, with an upper surface 42 of the vaporizer main body 30 recessed in the same way as the liquid filling container 35. The bottom of the mixing container 36 is connected to the dilute gas lead-in port 41 provided on the side surface of the vaporizer main body 30 through the dilute gas lead-in path 34 provided within the vaporizer main body 30. The dilution gas lead-in path 34 is narrowed down from the midway and connected to the mixing container 36. The reason for narrowing down the dilute gas lead-in path 34 from the midway is that the liquid source is pushed out from the orifice 39 by increasing the flow rate of the dilute gas. The dilute gas is supplied to the vaporizer 3 in a state of being heated. The dilute gas is heated up to the temperature at which the liquid source is vaporized when the dilute gas and the liquid source is mixed in the vaporizer 3. The “temperature at which the liquid source is vaporized” is an optimal temperature for vaporizing the liquid source, and is the temperature, although different according to the kind of the liquid source and the shape and a heat capacity of the vaporizer 3, higher by about 10 to 20° C. than a vaporization temperature, for example, to compensate the heat removed in the middle of a process. The heated dilute gas is sent to a dilute gas supply pipe 10. The aforementioned dilute gas flow path 34 is constituted of the dilute gas lead-in path 34 and the dilute gas lead-in port 41.

In addition, the bottom of the mixing container 36 is connected to the vaporization container 40 through the orifice 39. The vaporization container 40 is provided to mix the liquid source spouted in a fine spray from the orifice 39 and the dilute gas, to be vaporized. Similarly to the mixture in the container 36, the mixture in the vaporization container 40 is an indispensable requirement. This is because when the liquid source spouted in a fine spray is not mixed with the heated dilute gas, the liquid source is not sufficiently vaporized. The vaporization container 40 is formed in a thickness direction of the vaporizer body 30 and is connected to the source gas lead-out port 43 provided on a lower surface of the vaporizer body 30. The vaporization container 40 has, with the orifice 39 as a top portion, a shoulder portion whose diameter is gradually increased downward from the top portion, and a trunk portion continuing from the shoulder portion having the same diameter with the shoulder portion.

A heater 44 is embedded in the vaporizer main body 30 and heats the vaporizer main body 30 to a temperature lower than the vaporization temperature of the liquid source. Here, the temperature lower than the vaporizing temperature is the temperature at which the liquid source is not adsorbed on the wall surface of the vaporizer main body but is desorbed from the wall surface, although lower than the vaporization temperature. Here, although different depending on the source, the “vaporization temperature” is 180° C. for PET (Ta (OC₂H₅)₅) and Hf(MMP)₄ (Hf[OC(CH₃)₂CH₂OCH₃]₄), and 120° C. for TDEAHf(Hf[N(C₂H₅)] ₄). Also, the “temperature lower than the vaporization temperature” is the temperature lower than the vaporization temperature by about 50° C., for instance. The reason for heating the vaporizer main body 30 is that the liquid source and the dilute gas introduced in the vaporizer main body 30 has to be kept warm. Moreover, the reason for heating the vaporizer main body 30 to the temperature lower than the vaporization temperature is that the liquid source introduced into the vaporizer main body 30 has to be prevented from self-decomposing due to the heat of the vaporizer main body 30, resulting in depositing on the vaporizer main body. Preferably, the heater 44 is provided so as to uniformly heat the vaporizer main body 30. In the example shown in the figure, the heater 44 is provided so as to surround the side of a downstream of the narrowed dilute gas flow path 34 and the side close to the orifice 39 of the vaporization container 40 in a ring-shape. In addition, in order to set the temperature of the vaporizer main body 30 at the temperature lower than the vaporization temperature of the liquid source, a temperature sensor 45 for measuring the temperature of the vaporizer main body, for example, a thermocouple is provided in the vaporizer main body 30. Note that the heater 44 may be provided along an outer periphery of the vaporizer main body 30, instead of providing within the vaporizer main body 30.

The valve element 33 controls the flow rate in the injecting operation of the liquid source to the vaporization section 31 by sealing a surface of the vaporizer main body 30 or releasing the sealing. The valve element 33 has a cylinder shape and is air-tightly attached to a top surface 42 of the vaporizer main body 30 so as to cover upper openings of the liquid filling container 35 and the mixing container 36. The valve element 33 comprises a cylinder 21, a piston 22 as a valve, a piston rod 23 and an actuator 24. The cylinder 21 is placed on the upper surface 42 of the vaporizer main body 30 and along the outer periphery of the ring-shaped liquid filling container 35, so as to surround the liquid filling container 35. The piston 22 is fitted into the cylinder 21 in a free elevation state. When the piston 22 rises within the cylinder 21 and separates from the upper surface 42 of the vaporizer main body 30 and space 25 is thereby formed, the liquid filling container 35 and the mixing container 36 are communicated to each other through the space 25, to thereby release the sealing of the liquid filling container 35. When the piston 22 lowers and is pressed on the upper surface 42 of the vaporizer main body 30, the communication between the liquid filling container 35 and the mixing container 36 are cut, and the liquid filling container 35 is sealed. An elevating operation of the piston 22 shown by a void arrow mark is performed by an actuator 24. The flow rate in the injecting operation of the liquid source to the vaporization section 31 is determined by a pulse-like electrical signal applied to an actuator 24, which is constituted of the amplitude, the pulse width, and the period. Note that a generally used cylinder type is adopted for the valve element 33, however, a valve other than the cylinder type may be adopted. The liquid source flow path 32 is constituted of the liquid lead-in port 38, the liquid source lead-in path 37, and the liquid filling container 35.

In the structure of the vaporizer 3 as described above, by supplying a carrier gas to the source container 2, the liquid source in the source container 2 is pressurized and is supplied to the vaporizer 3 through the liquid source supply pipe 4 kept warm as needed. Moreover, the dilute gas for diluting the liquid source is heated and supplied to the vaporizer 3, through the dilute gas supply pipe 10 thus kept warm. The liquid source supplied to the vaporizer 3 and the dilute gas are mixed, heated and vaporized in the vaporizer 3. The source gas thus vaporized is supplied to the processing chamber 1 from the vaporizer 3 through the source gas supply pipe 5 thus kept warm and exhausted therefrom. At this time, the vaporized gas contributes to the deposition on the substrate.

Next, action of the vaporizer 3 thus constituted will be explained. The valve element 33 in a closed state is located at a position of a dotted line, with the piston 22 lowered, and the liquid filling container 35 is sealed. The liquid source is pressed into the vaporizer main body 30 from the liquid lead-in port 38, and stored in a sealed liquid filling container 35 through the liquid source lead-in path 37. The liquid source is spouted from the orifice 39 by elevating the piston 22 to the position of solid line to release the sealing of the liquid filling container 35, and the space 25 is formed on the upper surface 42 of the vaporizer main body 30 within the cylinder 21, to thereby communicate the liquid filling container 35 and the mixing container 36 through the space 25. By this communication between the liquid filling container 35 and the mixing container 36, the liquid source stored in the liquid filling container 35 flows into the mixing container 36.

Meanwhile, the dilute gas thus heated is always supplied to the vaporizer main body 30, irrespective of the opening/closing of the valve element 33. Specifically, the dilute gas flows into the mixing container 36 through the dilute gas lead-in path 34 from the dilute gas lead-in port 41, with the flow rate increased in the middle thereof, and thereafter the dilute gas thus flowing in is exhausted from the vaporization container 40 through the orifice 39 via the source gas lead-out port 43.

Accordingly, when the valve element 33 is opened, the liquid filling container 35 and the mixing container 36 are communicated and the liquid source flows into the mixing container 36. Then, the liquid source is immediately mixed with the dilute gas in the mixing container 36, with the dilute gas being increased in a flow speed. The liquid source thus mixed is diluted to an amount easy to be vaporized and pushed out from the orifice 39 by the dilute gas. At this time, the liquid source is spouted in fine spray from the orifice 39 to the vaporizer 40 and mixed with the dilute gas pushed out together with the liquid source in the vaporization container 40. Since being formed in fine spray, the temperature of the liquid source is increased up to the vaporization temperature by the dilute gas thus heated, and instantly vaporized. The source gas thus vaporized is exhausted from the source gas lead-out port 43 as shown by an arrow mark.

As described above, when the electric signal instruction constituted of the pulse width, the amplitude, and the period is sent to the actuator 24 of the valve element 33 of the vaporizer 3 from the injection drive control mechanism 6, and the piston 22 is operated upward according to the instruction, the liquid source stored in the liquid filling container 35 is injected instantly into the mixing container 36, and is vaporized in the vaporization container 40 through the orifice 39.

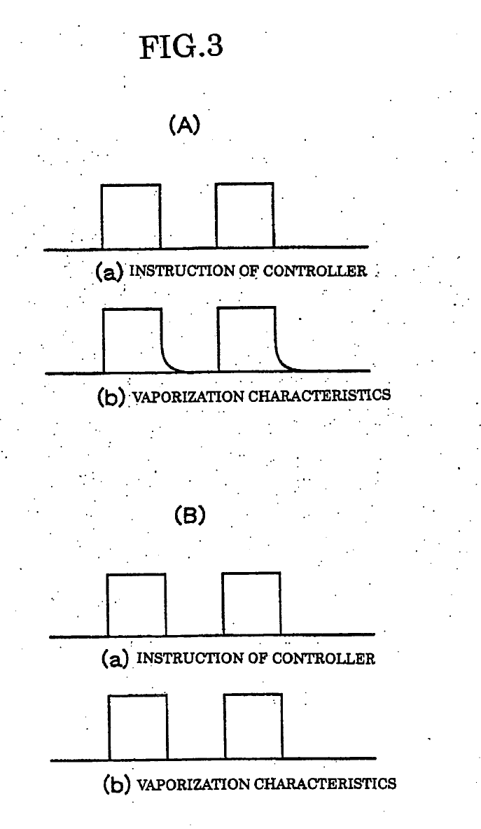

The vaporization characteristics of the aforementioned injection system compared with the vaporization characteristics of other system will be explained hereunder. For instance, in a vaporization unit used in the patent document 1, the liquid flow rate controller and the vaporizer are provided separately and connected by a pipe. In the patent document 1 thus constituted, the vaporization characteristics as instructed by the controller (a) can not be obtained as shown in FIG. 3(A) due to a time difference caused by flowing of the liquid between two elements and a liquid residue in the piping, and sag of the falling is thereby caused as shown in FIG. 3(A)(b). In this point, in the vaporizer 3 according to the embodiment, the vaporization section is disposed immediately under the liquid flow rate control valve element 33, and therefore the influence of such a time difference and the liquid residue can be significantly reduced. As a result, as shown in FIG. 3(B), the vaporization characteristics of steep falling (b) as instructed (a) by the injection drive control mechanism 6 can be obtained.

Incidentally, according to the present invention, the flow rate per one injecting operation is dependent on the pressure of N₂ that forcibly sends the liquid source to the vaporizer 3. Accordingly, in order to fix the flow rate per one injecting operation irrespective of the pressure of N₂, it is necessary to previously obtain the correlation between the pressure of the N₂ thus forcibly sent and the flow rate per one injecting operation of the liquid source, and correct the injection flow rate from the correlation thus obtained.

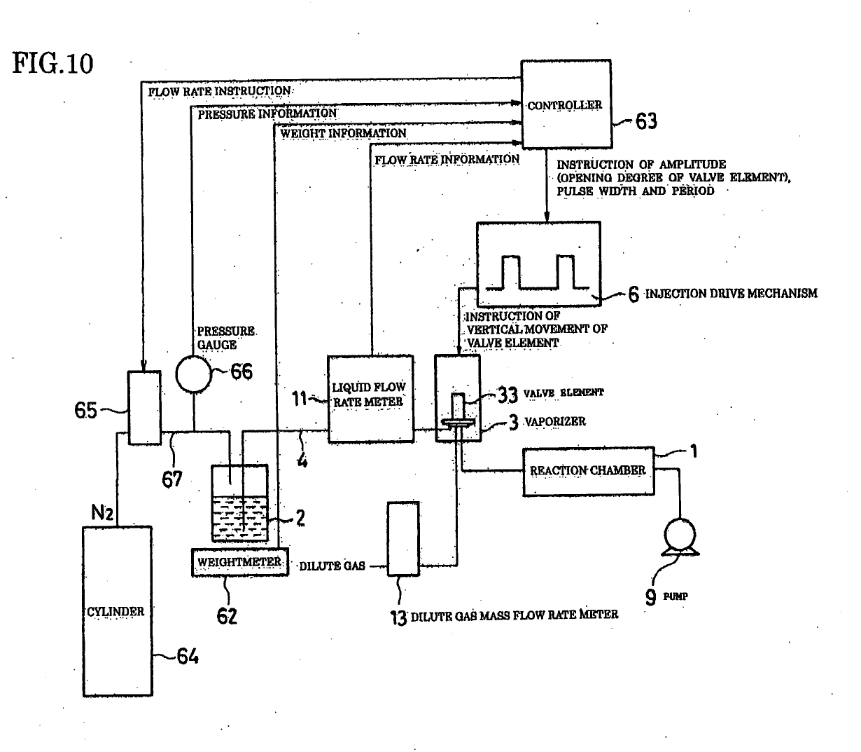

A method for fixing the flow rate described above will be specifically explained with reference to FIG. 1. An amount per one injection is obtained in such a manner that the feeding pressure of N₂ is maintaining at a certain constant pressure, thereby causing the liquid source to be injected at a speed of several tens Hz from several hundreds to several thousands times, with a certain determined opening degree of the valve element 33, then by the injection drive control mechanism 6, the flow change at that time is observed based on the flow rate notified from the liquid flow meter 11, and the integrated value thus obtained is used as an integrated flow rate. Here, usually the flow rate is controlled by constituting the liquid flow meter 11 by the mass flow controller, the mass flow controller and the vaporizer 3 are electrically connected as shown by a dotted line, and the flow rate flowing into the vaporizer 3 is controlled to be fed back to the mass flow controller. However, here, the mass flow controller and the vaporizer are not electrically connected as shown by x mark, and such a usual flow control is not performed. Note that when the liquid source is injected at the aforementioned speed, the flow rate of the liquid is fluctuated at a high speed, and in some cases, the value shown by the liquid flow meter 11 is not reliable. In this case, the flow rate needs to be observed by the fluctuation in weight of the source container 2 in which the liquid source is stored. Specifically, as shown in FIG. 10, a scale 62 is disposed under the source container 2, a flexible piping is used for the piping to the source container 2, so as to correctly reflect the fluctuation in weight of the source container 2 on the scale 62.

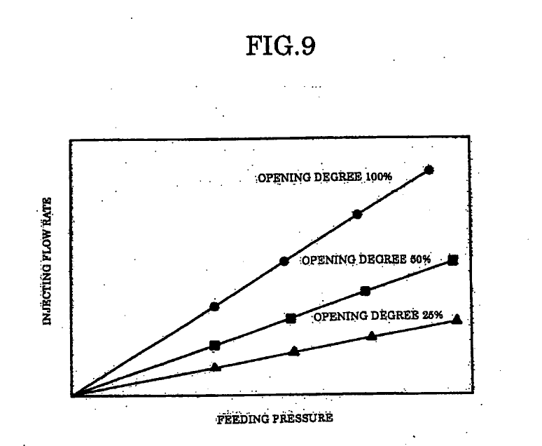

By the aforementioned method, when measuring several patterns of relations between the feed-pressure of N₂ to the injection flow rate, using the valve opening degree as a parameter, the flow rate characteristics as shown in FIG. 9 can be obtained. Based on the flow rate characteristics, the feeding pressure of N₂ and the opening degree of the valve element required for obtaining the necessary injecting flow rate are determined. In this case, the flow rate characteristics are stored in the injection drive control mechanism 6 as electronic data (lookup table), and a user sets the flow rate per one injecting operation in the injection drive control mechanism 6. Under the program incorporated in the injection drive control mechanism 6, the pressure and the opening degree of the valve element are obtained from the aforementioned lookup table, and a set flow rate is controlled so as to be corrected to the value thus obtained.

As described above, the flow rate is corrected based on the relation between the pressure of the liquid feed pressure and the injecting flow rate. This contributes to fixing the flow rate per one injecting operation to the vaporization section 31 of the liquid source, even if the feed pressure of N₂ is fluctuated. Incidentally, the flow rate per one injecting operation is considered to be changed with passage of time. In order to improve the change of the flow rate with the passage of time, it is necessary to monitor the flow rate with passage of time and adjust the amount of injection.

FIG. 10 shows a block diagram of the substrate processing apparatus capable of improving such a fluctuation of the flow rate with passage of time. The substrate processing apparatus of FIG. 10 is different from the substrate processing apparatus shown in FIG. 1 in that an upper controller 63 electrically connected to the injection drive control mechanism 6 is provided. Pressure is informed to the upper controller 63 from a pressure gauge 66 for measuring the pressure within an N₂ gas supply pipe 67 by which an N₂ gas cylinder 64 and the source container 2 are connected. Also, weight is informed to the upper controller 63 from the scale 62 disposed under the source container 2, for measuring the weight of the container. In addition, the flow rate is informed to the upper controller 63 from the liquid flow meter 11 disposed in the liquid source supply pipe 4, for measuring the flow rate of the liquid flowing through the liquid source supply pipe 4. Meanwhile, the flow rate is instructed from the upper controller 63 to a mass flow controller 65 provided in the N₂ gas supply pipe 67, by which the N₂ gas cylinder 64 and the source container 2 are connected. Furthermore, instruction of the amplitude (opening degree of the valve element), the pulse width, and the period is given to the injection drive control mechanism 6.

An integrated injecting flow rate corresponding to several hundreds to several millions times of injection is calculated by the upper controller 63 based on the electrical signal from the liquid flow meter 11 informing the flow rate. Such an integrated injecting flow rate is stored in the upper controller 63, and whether or not the amount per one injection is changed with passage of time is monitored. When the amount per one injection is changed and such a change falls within an allowable range of several to ten and several percent capable of correcting the change with passage of time, the upper controller 63 defines that there is a change in the characteristics of the vaporizer 3 or the injection drive control mechanism 6. Then, an instruction is given to the vaporizer 3, so that the valve element is vertically moved for adjusting the change in the amount of one injection with passage of time, and the opening degree of the valve element 33 is thereby adjusted. However, when the amount of change exceeds the allowable range, an alarm showing the service life of the vaporizer 3 is displayed, and replacement of the vaporizer 3 is urged. Note that the change in the characteristics of the aforementioned injection drive control mechanism 6 is caused by a deterioration of the piezo valve used in the injection drive control mechanism. This is because the piezo valve is formed of a ferroelectric material and the ferroelectric material fatigues by continuing the operation for a long time.

According to the embodiment shown in FIG. 10, an integrated flow rate of a constant time/constant number of injection is calculated based on the electric signal from the liquid flow meter 11 at the upper controller 63, and the integrated flow rate thus calculated is monitored, to thereby adjust the change in an amount of one injection with passage of time. This contributes to improving the reliability of the liquid source supply system, and always maintaining a processing accuracy of a wafer.

Note that the lookup table with the aforementioned flow rate characteristics is not be held by the injection drive control mechanism 6 in the system shown in FIG. 10, but held by the upper controller 63 electrically connected to the injection drive control mechanism. With this structure, by setting the flow rate in the controller 63 by a user, and obtaining the pressure and the opening degree of the valve element 33 from the lookup table under the program incorporated therein, the instruction may be given to the injection drive control mechanism 6.

Note that according to the present invention, in fixing the flow rate per one injection operation to the vaporization section of the liquid source, the flow rate flowing into the vaporizer 3 is not fixed, but the flow rate flowing into the vaporization section 31 of the vaporizer 3 is fixed. Accordingly, the vaporizer 3 is not limited to a valve integrated type, but is applicable to a separate type valve element 33.

According to a general explanation given in the aforementioned embodiments, the method of manufacturing the semiconductor device is limited to the process of depositing by supplying a plurality of gases and repeating such a supply for a plurality of times, although the process is not limited to either of the MRCVD method or the ALD method. Here, the present invention will be further specifically explained by limiting the method to the ALD method.

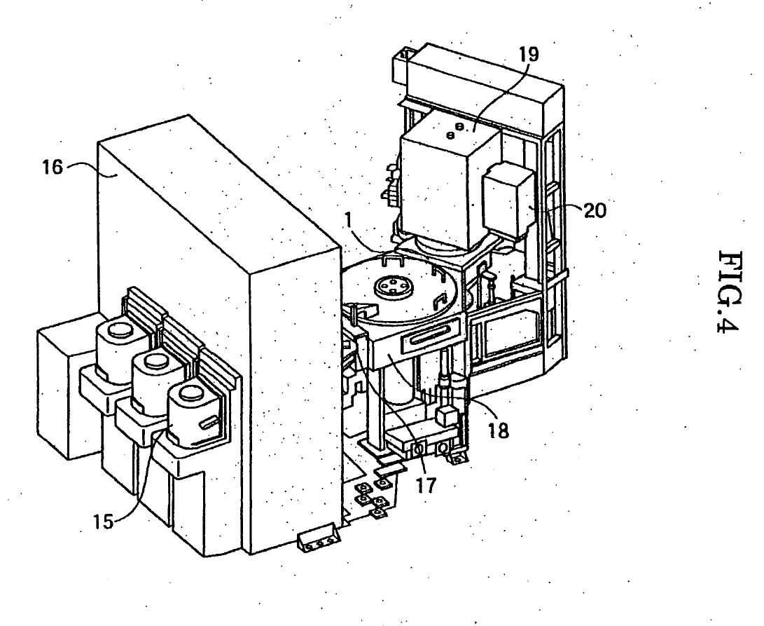

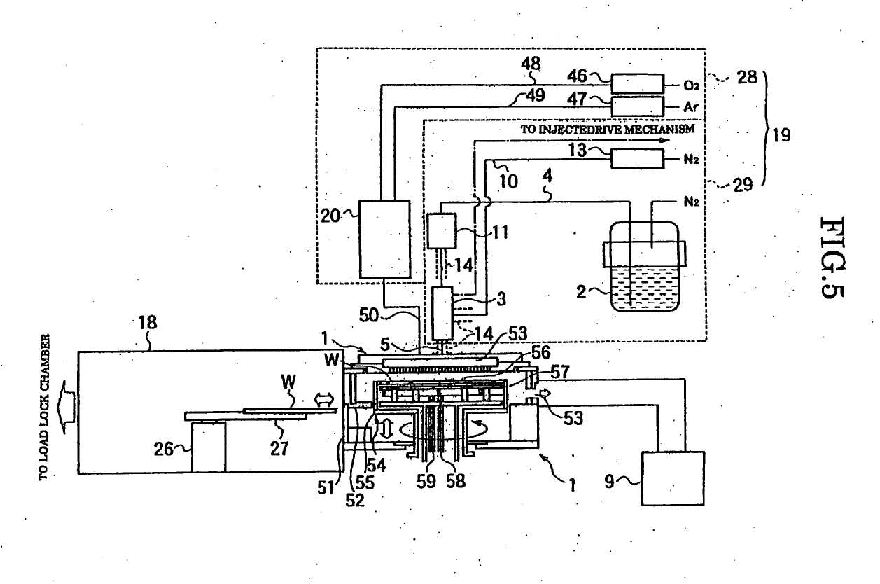

FIGS. 4 and 5 show the structure of an ALD device having particularly larger merit when the present invention is applied. In this example, it is assumed that an oxide film is deposited on the wafer as a substrate.

The ALD device is frequently used in a cluster type semiconductor manufacturing device as shown in FIG. 4. Such a device is mainly constituted of an atmosphere wafer carrying mechanism 16, a load lock chamber 17, a vacuum carrying chamber 18, and a processing chamber 1. The processing chamber 1 includes a reactant supply system 19 and a remote plasma unit 20 installed therein. In the reactant supply system 19, the flow rate of the liquid source is controlled to be vaporized and supplied, and in the remote plasma unit 20, oxygen is generated, and the oxygen thus generated is activated and used as a reactive gas.

The wafer is transferred from a wafer cassette 15 to the atmosphere wafer carrying mechanism 16, so that the wafer is introduced in the load lock chamber 17, and the load lock chamber 17 is evacuated from atmospheric pressure to vacuum. Next, the wafer is carried to the processing chamber 1 through the vacuum carrying chamber 18. In the processing chamber 1, the vaporized gas and the activated oxygen are alternately switched and supplied, so as to be deposited on the wafer up to a desired thickness. After the deposition, the wafer is returned to the wafer cassette 15 by the opposite flow of the aforementioned flow.

FIG. 5 shows a detailed drawing of an essential part of FIG. 4 constituted of the vacuum carrying chamber 18, the reactant supply system 19, the remote plasma unit 20 and the processing chamber 1.

The vacuum carrying chamber 18 is provided with a transfer robot 26 in the chamber. The transfer robot 26 has an expandable and rotatable arm 27 and carries a wafer W held on the arm 27. One side of the vacuum carrying chamber 18 is connected to the load lock chamber and the other side is connected to the processing chamber 1. The transfer robot 26 receives the wafer W before processing from the load lock chamber, transfers it to the processing chamber 1 and places it on a susceptor 56. Also, the transfer robot 26 receives an already processed wafer W from the processing chamber 1 and transfers it to the load lock chamber to place therein.

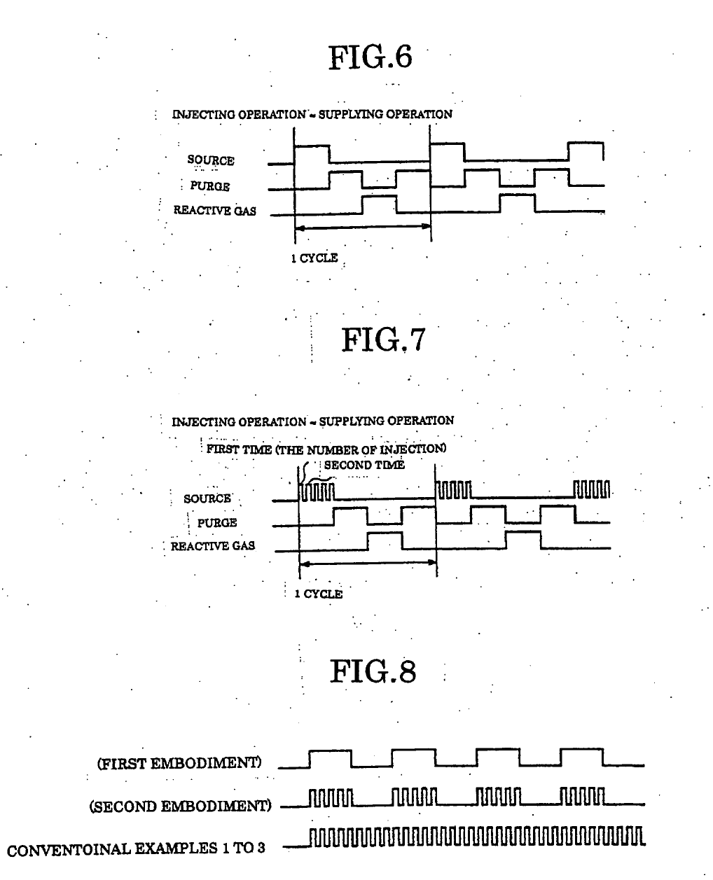

In the ALD method, as shown in FIG. 6, the deposition is repeated by setting four steps of supplying source, purging, supplying the reactive gas, and purging as one cycle of a reactant introduction sequence. The reactant supply system 19 is used as the reactant supply step. The reactant supply system 19 includes two systems of a reactive gas supply system 28 and a liquid source vaporization system 29. In the reactive gas supply system 28, the activated oxygen is supplied to the processing chamber 1 as a reactive gas by supplying a remote plasma source to the remote plasma unit 20, and in the liquid source vaporization system 29, the liquid source is vaporized and supplied to the processing chamber 1.

The reactive gas supply system 28, though schematically shown here, is mainly constituted of an O₂ supply pipe 48 for supplying oxygen (O₂) and an Ar supply pipe 49 for supplying an argon (Ar) gas that are respectively provided with mass flow controllers 46 and 47. The O₂ gas and the Ar gas are supplied from an O₂ supply pipe 48 and an Ar supply pipe 49, and the Ar injection is generated to produce plasma and O₂ is excited and activated by this plasma at the remote plasma unit 20. The activated O₂ is supplied to a reactive gas supply pipe 50 from the remote plasma unit 20 together with Ar plasma.

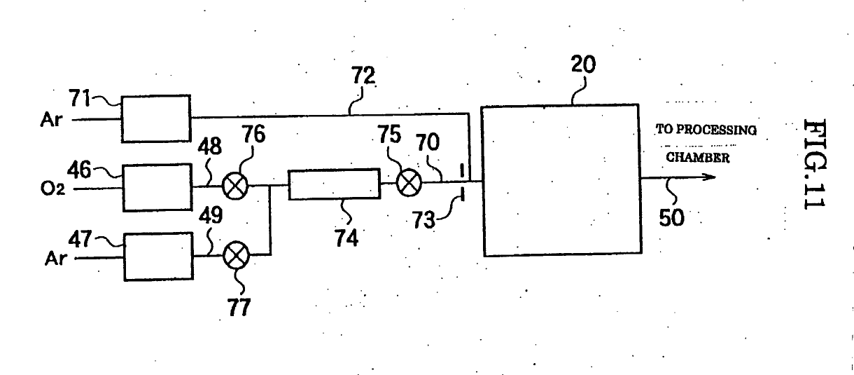

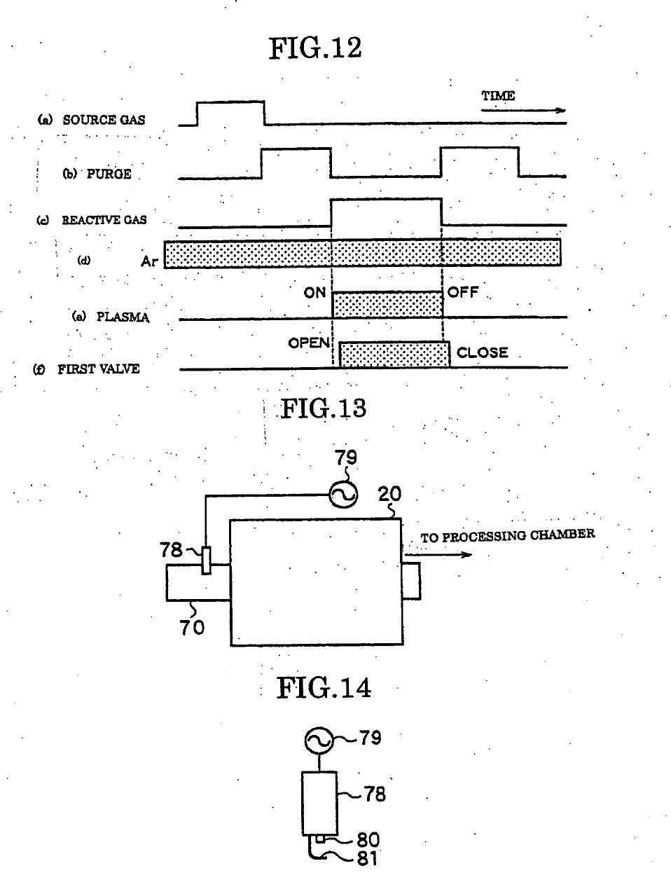

The activated oxygen is controlled at high speed so as to match with the control speed of the liquid source controlled by the injection drive control mechanism, and such a control at high speed is performed by on/off controlling the plasma. The reactive gas supply system 28 is specifically constituted as shown in FIG. 11, and the oxygen activated at high speed is sent to the processing chamber, following after the sequence shown in FIG. 12.

The reactive gas supply system shown in FIG. 11 includes a remote plasma unit 20 and piping 72 and 70. Ar flows through the piping 72 and a mixed gas of oxygen O₂ and argon Ar flow through the piping 70. The reactive gas supply pipe 50 is connected to the lead-out side of the remote plasma unit 20, and the activated oxygen is supplied to the processing chamber through the reactive gas supply pipe 50. The piping 70 is connected to the lead-in side of the remote plasma unit 20, and the piping 72 is connected to the piping 70 so as to be merged with each other, and the mixed gas of O₂ and Ar is supplied to the remote plasma unit 20.

The O₂ supply pipe 48 and the Ar supply pipe 49 are connected so as to be merged with each other, and connected to the aforementioned piping 70. The piping 70 through which the mixed gas flows, includes a mixer 74, a second valve 75, a restrictor 73 from an upstream side to a downstream side. The restrictor 73 is provided on the upstream side of a merged connection point with the piping 72. In addition, the mass flow controllers 71, 46, and 47 are respectively provided in the piping 72, the O₂ supply pipe 48, and the Ar supply pipe 49 and further a second valve 76 and a third valve 77 are respectively provided in the O₂ supply pipe 48 and the Ar supply pipe 49.

The Ar led-in from the piping 72 always flows into the processing chamber through the remote plasma unit 20. This is because the vaporized gas, which is the other source, is prevented from diffusing and entering the remote plasma unit 20. If the vaporized gas enters the remote plasma unit 20, the vaporized gas is reacted by plasma, thereby causing particles. Further, in the mixer 74, the second valve 76 and the third valve 77 are opened for a fixed time, with the first valve 75 being in a closed state, and the mixed gas of Ar and O₂ are sealed, with the second valve 76 and the third valve 77 closed. This is because when the first valve 75 is opened and a large quantity of oxygen is led-in the remote plasma unit 20, there is a possibility that the plasma is extinguished. However, depending on the capability of the remote plasma unit 20, such a valve opening and closing may be eliminated.

In addition, in the piping 70 disposed between the first valve 75 and the remote plasma unit 20, the restrictor 73 is inserted for adjusting the flow rate of the mixed gas by adjusting a flow path cross section, and a large quantity of gas is inhibited from flowing thereinto. That is, the flow rate is fixed. When the reactive gas is led-in the sequence of FIG. 6, as shown in FIG. 12, the plasma is set in an on-state, and the first valve 75 is opened to flow the mixed gas of Ar and oxygen O₂. Meanwhile, when the lead-in of the reactive gas stops, the plasma is set in an off-state, and the first valve 75 is closed. Here, when the plasma is set in an on-state, as shown in FIG. 13, in order to generate the plasma (called the actual plasma), it is effective that a small-sized plasma generator 78 is installed in the piping 70 on the upstream side of the remote plasma unit 20, and a minimum power is inputted from a high frequency power source 79, to generate a slight amount of plasma (preliminary plasma). A small-sized plasma generator 78 is shown in FIG. 14. Small power is inputted between terminals 80 and 81 separated apart by about several hundred micrometers to several millimeters from the high frequency power source 79, and minute plasma is thereby generated.

As described above, at the mass flow controller, the reactive gas is not controlled but the flow rate of the activated oxygen is controlled by the restrictor 73 of which the flow rate is previously set, and then the oxygen O₂ is instantly activated by the preliminary plasma and the actual plasma. Therefore, the activated oxygen can be sent to the processing chamber at high speed.

Now, the explanation will be returned once more to FIG. 5. The liquid source vaporization system 29 includes the source container 2, the liquid flow meter 11, the vaporizer 3, the liquid source supply pipe 4, the dilute gas supply pipe 10 provided with the mass flow controller 13, and a heater 14. The liquid source is forcibly fed by the N₂ gas from the source container 2 to the liquid source supply pipe 4, and supplied to the vaporizer 3 through the liquid flow meter 11. Here, the vaporizer 3 is controlled by the injection control mechanism, and the liquid source is injected to the vaporizer 3, with the flow rate per one injection fixed, for a time corresponding to the pulse width. The liquid source thus injected is mixed with the dilute gas N₂ supplied from the dilute gas supply pipe 10 so as to be diluted therein, and injected to the vaporization section. The vaporized gas thus vaporized at the vaporization section is intermittently led-in the source gas supply pipe 5, responding to the pulse-like controlling electrical signal.

The heaters 14 are provided in the liquid source supply pipe 4, the source gas supply pipe 5 and the dilute gas supply pipe 10, and the piping is thereby heated as needed, so as not to reduce the temperature of the liquid or the gas carried in the piping.

One sheet of substrate is processed, for example, in a sheet-fed processing chamber 1. A wafer carrying port 52 is provided on one side of the processing chamber 1, for leading to the vacuum carrying chamber 18 through a gate valve 51. An exhaust port 53 is provided on the other side of the processing chamber 1, and the processing chamber 1 can be exhausted by a pump 9. A showerhead 53 is provided on the upper part of the processing chamber 1, and the source gas supply pipe 5 and the reactive gas supply pipe 50 are connected thereto, so that two kinds of gases can be supplied on a wafer W in shower from such supply pipes 5 and 50. In addition, a purge gas supply pipe not shown is connected to the showerhead 53, so that the purge gas is led-in the processing chamber 1 and can be supplied on the wafer W.

A heater unit 54 functions to hold and heat the wafer W, and provided so as to be freely elevated in a direction shown by a vertical arrow mark in the processing chamber 1, and rotatable as shown by an arrow mark. The heater unit 54 includes a unit main body 55, a susceptor 56 provided in the upper part of the unit main body 55, for holding the wafer, and a heater 57 provided in the inside of the unit main body 55 for heating the wafer W through the susceptor 56. Note that from the inside of the unit body 55, an optical fiber 58 or a thermocouple 59 necessary for controlling a wafer temperature is drawn out to the outside of the processing chamber 1. At depositing, as illustrated in the drawing, the heater unit 54 is elevated so that the wafer W is positioned in the vicinity of the showerhead 53, and when the wafer is carried, the heater unit 54 is lowered so that the susceptror 56 is positioned to face a wafer carrying port 52.

An action of the aforementioned ALD device will be explained hereunder. The transfer robot 26 installed in the vacuum carrying chamber 18 takes out the wafer W from the load lock chamber. When the wafer W is carried to the processing chamber 1, the heater unit 54 constituted of the susceptor 56 and the heater 57 is lowered, the wafer carrying port 52 and the surface of the susceptor 56 are made into the same height, and the wafer W is sent into the processing chamber 1 by the arm 27 of the transfer robot 26 by opening the gate valve 51. At this time, three pushing-up pins (not shown) rise from under the susceptor 56, so as to hold the wafer W. Next, the arm 27 of the transfer robot 26 is taken out from the processing chamber 1, and the gate valve 51 is closed. Then, the pressure within the processing chamber 1 is reduced by evacuating through the exhaust port 53 by the pump 9.

The heater unit 54 is elevated, the pushing-up pins are lowered downward, and the wafer W is placed on the susceptor 56. The heater unit 54 is further elevated, and the wafer W held on the susceptor 56 is moved to a position to make the distance between the wafer W and the showerhead 53 10 mm to 20 mm, for example. Then, the wafer W is rotated together with the susceptors 56. At this time, the heater 57 is fixed. The wafer W is rotated for relieving the non-uniformity of temperature in the surface of the wafer due to heating by the heater 57. When a predetermined pressure is obtained within the processing chamber, and the temperature of the wafer W becomes close to the temperature of the susceptor to be nearly fixed, the deposition process by the ALD method is executed.

In the ALD method, as shown in FIG. 6, the deposition is repeated by four steps of supplying source, purging, supplying reactive gas, and purging, as a one cycle. The liquid source vaporization system 29 and the reactive gas supply system 28 are used in the reactant supply step.

(1) Source Supplying Step

By the liquid source vaporization system 29, the liquid source is injected and vaporized from the source container 2 to the vaporization container 31 of the vaporizer 3. Then, the source gas A thus vaporized is led-in the processing chamber 1, so that the gas source is adsorbed on the surface of the wafer W.

(2) Purging Step

After the adsorption, a non-reactant including an inert gas and so on is led-in the processing chamber 1, and an extra gas A in the processing chamber 1 is removed by exhausting from the exhaust port 53.

(3) Reactive Gas Supplying Step

After the extra gas A is removed, a plasma-excited reactive gas B (activated O₂) capable of forming an oxide thin film by reacting with the gas source adsorbed on the substrate is led-in the processing chamber 1 from the reactive gas supply system 28, to thereby form one atomic layer of a thin film on the wafer by a wafer surface reaction.

(4) Purging Step

After the one atomic layer is formed, the non-reactant including the inert gas and so on is led-in the processing chamber 1, and the extra gas B and a reactive by-product are removed by exhausting from the exhaust port 53, by leading-in the non-reactant including the inert gas.

By using the steps (1) to (4) as one cycle, a plurality of cycle processings are executed until a desired film thickness is obtained. When the desired film thickness is obtained, rotation of the heater unit 54 is stopped, and the heater unit 54 is lowered so that the height up to the surface of the susceptor 56 is made into nearly the same height as the wafer carrying port 52. Subsequently, the pushing-up pins are raised, the wafer W is separated from the susceptor 56, and the gate valve 51 is opened to thereby take out the wafer W from the processing chamber 1 by the transfer robot 26.

In such an ALD method, under predetermined conditions, the film thickness formed per one cycle is determined, and the processing of the number of cycles within a required time is needed for forming the desired film thickness within a required time. In order to perform the necessary number of cycles during the required time period, a time per cycle is logically determined. However, in order to attain an upper limit of the number of available sheets of deposition per time satisfying economical efficiency on productivity, that is, to attain throughput, in some cases, the time limit within one second is required for the time per one cycle.

In this case, the aforementioned gases A and B and the non-reactant have to be supplied to the processing chamber 1 for only quarter seconds, when the time required for each step is set to be same. When the gas A is generated by vaporizing the liquid, a quick operation is required such as flowing a constant amount of flow for only a quarter second period. In this point, in the liquid source supply system 19 of the abovementioned ALD device, a quick operation such as flowing a constant amount of flow for only a quarter second period can be easily realized, by controlling the amount of injection to the vaporization section 31 while performing an open-loop control of the amount of injection according to an injection command from the injection drive control mechanism. In addition, in the reactive gas supply system 28 as well, the quick operation such as flowing a constant amount of flow for only a quarter second period can be easily realized by controlling the flow rate to the processing chamber 1 by the restrictor 73 and the on/off control of plasma. Accordingly, particularly preferably the ALD method is used in the reactant supply system 19 of the embodiment.

Further, in the ALD method, the gases are switched by the sequence shown in FIG. 6. However, in a cycle of purging after leading-in the source, it is desired to completely exhaust residual extra sources. When a conventional system is applied to the ALD method, wherein the controller is formed as a separate body from the vaporizer, the sag of the falling of the vaporization characteristics is caused as shown in FIG. 3(A) (b). Meanwhile, in the system of the embodiment in which the controller is integrally formed with the vaporizer, the source can be sealed with good response to the command of the injection drive control mechanism 6, as shown in FIG. 3(B) (b). Therefore, the source can be completely exhausted from the processing chamber 1 during a purge sequence. In addition, the activated oxygen, which is the reactive gas, can also be completely exhausted from the processing chamber 1 during the purge sequence.

Further, in the ALD method, since the deposition mechanism is self-limited, a deposition film thickness per cycle becomes from several to several tenth A. Accordingly, in order to improve a deposition rate per unit time, as shown in FIG. 6, a period of one cycle has to be shortened as much as possible. From this point of view, the system of the embodiment capable of controlling the injection/non-injection (leading-in/sealing) of the source at high speed by the open loop control is excellent compared with the feedback control system. In addition, in recent years, even when the deposition mechanism is not self-limited, the processing of repeating the deposition by leading-in the source for a short period of time at a unit close to the atomic layer, and oxidization or nitriding by leading-in the reactive gas and the removing of impurities are sometimes called ALD. The present invention can be applied to such systems, and such systems are excellent compared with the conventional system. Note that as the processing of repeating the deposition at the unit close to the atomic layer by leading-in the source for a short period of time and removing impurities, an MRCVD method is given as an example, in which the deposition by supplying the gas obtaiend by vaporizing an organic liquid source and a reformation by supplying plasma excitation gas are repeated.

Furthermore, as an example of a device for the ALD deposition, as described above, like patent literature 4, there is a method in which sources are switched in a valveless shape at a high-speed by using a vapor phase barrier. In this case, a demerit is that since the source is continuously supplied, the source is wastefully used other than introducing into the reaction chamber, thus increasing the cost accordingly. In this point, in the valve element or valve switching method according to the embodiment, only when the source is led-in the processing chamber, the source is consumed, and therefore source resources can be effectively utilized.

Incidentally, in the abovementioned ALD method, as shown in FIG. 6, explanation was given to the case of controlling the liquid flow rate per one injecting operation of the liquid source to the vaporization section 31 so as to be made equal to the flow rate corresponding to one supplying operation of the vaporized gas to the substrate, that is, the case of controlling one injection in one step (First embodiment). In this case, for instance, when the vaporization of the liquid source is progressed, the heat of vaporization is taken away from an inner wall of the vaporizer 3, particularly from an inner wall of the vaporization container 40, on which the liquid source is directly contacted, and the temperature is thereby lowered, resulting in deterioration of vaporization efficiency. In order to inhibit this from occurring, for instance, as shown in FIG. 7, preferably the sequence of supplying the liquid source is changed in such a way that the flow rate of the liquid source per one injection to the vaporization section 31 is made smaller than the flow rate corresponding to one supplying operation of the vaporized gas to the wafer, and the flow rate is controlled by the number of injection (Second embodiment). In this way, the flow rate of the liquid source per one injecting operation to the vaporization section is made smaller than the flow rate corresponding to one supplying operation of the reactant to the substrate, and the injection is divided into a plurality of numbers in one step, and by the number of the injection, the flow rate is controlled. In this condition, a non-injecting period is formed, in which the liquid source is not injected to the vaporization section during one supplying operation period, and in such a period, the temperature of the vaporization section, which is lowered, can be recovered. Accordingly, deterioration in the vaporization efficiency which is caused by the temperature drop of the vaporization section can be prevented.

Note that difference in an injecting method between the embodiments and the patent documents 1 to 3 (conventional examples 1 to 3) is shown in FIG. 8. The ALD is shown in the embodiments, in which a plurality of reactants and the non-reactants are alternately supplied, with supply of the non-reactants put between the reactants. Therefore, when other reactant and the non-reactant is supplied, the intermittent supply of one reactant is cut. Meanwhile, the CVD and the MOCVD are shown in the conventional example, in which a plurality of reactants are mixed and continuously supplied. Therefore, the intermittent supply of the reactant is not cut.

Note that in the aforementioned embodiments, as the reactive gas supply system for leading-in the reactive gas for ALD deposition at high speed, explanation was given to the case of treating oxygen O₂ by the reactive gas for which a remote plasma unit is required. However, depending on the kind of the reactive gas, the reactive supply system different from the above case needs to be adopted. This will be explained by using ozone O₃ and water H₂O as examples.

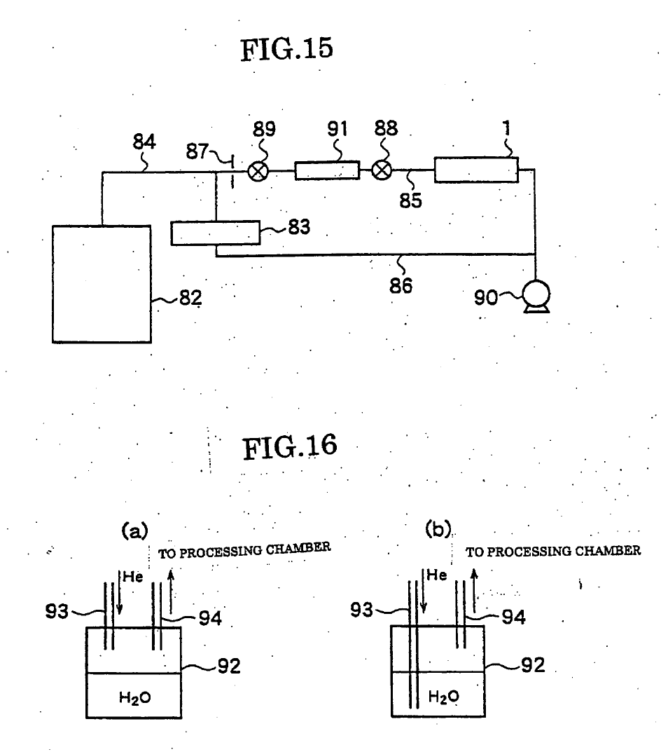

In the case of ozone, as the reactive gas supply system, a structure as shown in FIG. 15 is used. The ozone flows from an ozone generator 82 through a pipe 84, always at a constant flow rate. The piping 84 is branched into a piping 85 and a bypass line 86 at the downstream of the piping 84. One of the branched piping 85 is connected to a pump 90 through the processing chamber 1. The other branched bypass line 86 is connected to the pump 90 through an ozone killer 83. The piping 85 is provided with, from upstream to downstream, a flow rate restrictor 87, a second valve 89, a storage container 91, and a first valve 88. The piping 85 and the bypass line 86 are evacuated from the processing chamber 1 side by the pump 90, and when the first valve 88 and the second valve 89 provided in the piping 85 are opened, ozone O₃ mainly flows toward the processing chamber 1 at a flow rate adjusted by the flow rate restrictor 87 provided in the piping 85. When the ozone O₃ is not led-in the processing chamber 1, the first valve 88 is closed. When the ozone O₃ is led-in the storage container 91 to a certain constant pressure, the ozone O₃ flows toward the bypass line 86, and, after going through the ozone killer 83, is exhausted. The ozone O₃ is led-in the processing chamber 1, by opening the first valve 88 and closing the second valve 89. When a more high-speed operation is required, the second valve 89 can be eliminated by adjusting the restrictor 87 and the flow rate from the ozone generator 82. Furthermore, the storage container 91 may be constituted of a piping.

When the reactive gas is H₂O, as the reactive gas supply system, pure water (deionized water) is filled in a water container 92 as shown in FIGS. 16(a) and 16(b). A first piping 94 for leading-out moisture is inserted into the water container 92. The ozone generator 82 is detached from the piping 84 of the system shown in FIG. 15, and the first piping 94 is connected to the piping 84, thereby connecting the water container 92 to the system instead of the ozone generator 82. Moisture vaporized from the first piping 94 in association with the vapor pressure is led-in the system. At this time, the inert gas such as He may be flowed from the second piping 93 shown in FIG. 16(a) as a carrier gas. Furthermore, as shown in FIG. 16(b), the second piping 93 may be inserted into water of the container 92 to perform bubbling.

Next, an embodiment of deposition by using the ALD method, to which the present invention is applied, will be shown. The liquid source contains a metal-ligand complex precursor, and the ligands are selected from the group consisting of alkyl, alkoxide, halogen, hydrogen, amide, imide, azide ions, nitric acid radicals, cyclopentadienyl, carbonyl and fluorine, oxygen and nitrogen substituted similar products thereof. As the reactive gas, water, oxygen and ammonia may be usually used. However, in some cases, radical or ion activated in some way may be used. Furthermore, the term “reactive” is used for the reactive gas. However, actually the reactive gas may not be reacted with the “source”, but may only to give energy to a self-decomposing reaction of the “source”. For instance, in some cases, a rare gas or inert gas activated by plasma may be used.

Here, as specific examples, TMA(Al(CH₃)₃ (trimethyl aluminum) or TDEAHf (Hf (N(C₂H₅)₂)₄ (tetrakis diethylamide hafnium) are used for the “source” and O₃ ozone is used for the “reactive gas”, and Al₂O₃ (alumina) or HfO₂ (hafnia: hafnium oxide) is deposited respectively. The pressure of the processing chamber is set in the range from 100 to 1 Pa. Furthermore, a temperature of a Si wafer is set in the range from 150 to 500 degrees centigrade depending on the self-decomposing temperature of the source gas. For instance, in the case of TMA and TDEAHf, the temperature is set in the range from 200 to 400 degrees centigrade.

Now, as shown in FIG. 6, the liquid source is deposited by repeating a cycle including four steps of leading-in the source, purging, leading-in the reactive gas and purging. In this case, a time of each one step is set in the range from 0.1 to several seconds. At this time, a deposition film thickness per cycle becomes in the range from substantially 0.7 to 2 Å depending on a wafer temperature. For instance, when Al₂O₃ or HfO₂ is used as a gate insulating film or capacitor insulating film, the deposition with thickness from 15 to 50 Å is performed by repeating several to several tens cycles.

### INDUSTRIAL APPLICABILITY

According to the present invention, when a substrate is processed by repeating the supply step of plural reactants for a plurality of times, the reactant can be switched at a high speed and a throughput of a substrate processing can be improved.

1. A method of manufacturing a semiconductor device, comprising:
supplying one reactant to a substrate;
supplying the other reactant to the substrate; and
processing the substrate by repeating the above steps for a plurality of times,
wherein both or either of the reactants contains a source gas obtained by vaporizing a liquid source in a vaporization section, a flow rate of the liquid source to the vaporization section per one injecting operation is fixed, and the liquid source is controlled to be intermittently injected to the vaporization section.

2. The method of manufacturing a semiconductor device according to claim 1, wherein the flow rate of the liquid source to the vaporization section per one injecting operation is made equal to the flow rate corresponding to one supplying operation of the source gas obtained by vaporizing in the vaporization section to the substrate.

3. The method of manufacturing a semiconductor device according to claim 1, wherein the flow rate of the liquid source to the vaporization section per one injecting operation is made smaller than the flow rate corresponding to one supplying operation of the source gas obtained by vaporizing in the vaporization section to the substrate, and the flow rate is controlled by the number of injection.

4. The method of manufacturing a semiconductor device according to claim 1, wherein the process of the step of processing the substrate is an ALD processing to form a film with a desired thickness by conducting a control of repeating for a plurality of times the steps of:
supplying the one reactant to the substrate so as to be adsorbed thereon; and
supplying the other reactant to the reactant thus adsorbed on the substrate to cause reaction, thereby forming a film.

5. A substrate processing apparatus, comprising:
a processing chamber for processing a substrate;
a container for containing a liquid source;
a vaporizer having a vaporization section for vaporizing the liquid source;
a liquid source supply pipe for supplying the liquid source contained in the container to the vaporizer;
a source gas supply pipe for supplying the source gas obtained by vaporizing in the vaporizer into the processing chamber;
an injection drive control mechanism for controlling so as to fix a flow rate of the liquid source to the vaporization section per one injecting operation, and intermittently inject the liquid source to the vaporization section;
a supply pipe for supplying a reactant different from the source gas into the processing chamber; and
a controller for controlling so as to repeat the supply of the source gas to the processing chamber and the supply of the reactant different from the source gas to the processing chamber, for a plurality of times.

6. The substrate processing apparatus according to claim 5, wherein the controller has a function to control the flow rate of the liquid source to the vaporizer per one injecting operation so as to be made equal to an amount corresponding to one supplying operation of the source gas obtained by vaporizing in the vaporization section to the substrate.

7. The substrate processing apparatus according to claim 5, wherein the controller further has a function to make the flow rate of the liquid source to the vaporization section per one injecting operation smaller than the flow rate corresponding to one supplying operation of the source gas obtained by vaporizing in the vaporization section to the substrate, and control the flow rate by the number of injection.

8. The substrate processing apparatus according to claim 5, wherein the controller further has a function to control so as to deposit on the substrate by using an ALD, by repeating for a plurality of times a step of supplying one reactant to the substrate to be adsorbed thereon, and a step of forming a film by supplying other reactant to the reactant already adsorbed on the substrate so as to be reacted thereon.

9. The substrate processing apparatus according to claim 5, wherein the controller further has a function to previously measure the correlation between a pressure for feeding the liquid source to the vaporization section and the flow rate per one injecting operation, and correct the flow rate per one injecting operation based on the correlation thus obtained.

10. The substrate processing apparatus according to claim 5, wherein a liquid flow meter is provided between the vaporization section and the container, and an injection drive control mechanism having a flow rate adjusting mechanism electrically connected to the liquid flow meter is installed, and the flow rate adjusting mechanism has a controller that calculates an integrated flow rate of a certain time period or a certain constant number of injection based on an electrical signal from the liquid flow meter, monitors the integrated flow rate thus obtained with passage of time, and adjusts a change in the flow rate to the vaporization section per one injecting operation with passage of time.

11. The substrate processing apparatus according to claim 5, wherein the vaporizer is constituted as an injection type vaporizer integrally comprising the vaporization section for vaporizing the liquid source, a flow passage for feeding the liquid source to the vaporization section, and a valve element for controlling the injection/non-injection of the liquid source to the vaporization section by opening/closing the valve, and controlling the flow rate of the liquid source fed to the flow passage at controlling the valve to open by adjusting an opening degree of the valve, wherein the adjustment of the opening degree and opening/closing of the valve element is performed by the injection drive control mechanism.
